(19) United States
(12) Patent Application Publication
(10) Pub. No.: US 2015/0096789 A1
(43) Pub. Date: Apr. 9, 2015

(54) ELECTRONIC COMPONENT EMBEDDED PRINTED CIRCUIT BOARD AND METHOD FOR MANUFACTURING THE SAME

(71) Applicant: Samsung Electro-Mechanics Co., Ltd., Suwon (KR)

(72) Inventor: Moon Il KIM, Daejeon (KR)

(73) Assignee: Samsung Electro-Mechanics Co., Ltd., Suwon (KR)

(21) Appl. No.: 14/272,961

(22) Filed: May 8, 2014

(30) Foreign Application Priority Data
Oct. 7, 2013 (KR) 10-2013-0119275

(51) Int. Cl. H05K 1/02; H05K 3/32; H05K 3/46; H05K 1/18

(52) U.S. Cl. CPC H05K 1/0271; H05K 1/184; H05K 3/321; H05K 3/4611
USPC 174/251; 29/837

(57) ABSTRACT

The present invention relates to an electronic component embedded printed circuit board and a method for manufacturing the same.

An electronic component embedded printed circuit board of the present invention includes a core having a cavity therein and internal circuit layers on upper and lower surfaces thereof; an electronic component inserted in the cavity and having an elastic body on an outer peripheral surface thereof; insulating layers laminated on the top and bottom of the core; external circuit layers patterned on the insulating layers; and vias formed in the insulating layers to electrically connect the internal circuit layers and the external circuit layers, wherein among the vias, the via in contact with the electronic component is connected through the elastic body.

### CROSS-REFERENCE TO RELATED APPLICATION

This application claims the foreign priority benefit of Korean Patent Application No. 10-2013-0119275 filed Oct. 7, 2013, the contents of which are incorporated herein by reference.

### BACKGROUND OF THE INVENTION

1. Field of the Invention

The present invention relates to an electronic component embedded printed circuit board, and more particularly, to a method for manufacturing an electronic component embedded printed circuit board that can improve bonding reliability of an embedded electronic component.

2. Description of the Related Art

As the size of substrates is limited and multiple functions of electronic devices are required with the miniaturization and thinning of the IT electronic devices including mobile phones, it is required to mount electronic components for implementing more functions in the limited area of the substrate.

However, as the size of the substrates is limited, since it is not possible to secure a sufficient mounting area of the electronic components, there is a demand for a technology of inserting electronic components like active devices, such as ICs and semiconductor chips, and passive devices in a substrate. In recent times, a technology of embedding an active device and a passive device in the same layer or a technology of embedding an active device and a passive device in a substrate by stacking the active device and the passive device has been developed.

Typically, a method for manufacturing an electronic component embedded printed circuit board forms a cavity in a core of a substrate and inserts various devices and electronic components such as ICs and semiconductor chips in the cavity. After that, a resin material such as prepreg is applied inside the cavity and on the core in which the electronic component is inserted to form an insulating layer as well as to fix the electronic component, and a via hole or a through hole is formed in the insulating layer and a circuit is formed by plating to allow the electronic component to conduct with the outside of the substrate.

At this time, a circuit pattern is formed inside and on the via hole or the through hole by plating to be used as an electrical connection means with the electronic component embedded in the substrate, and a multilayer printed circuit board in which the electronic component is embedded can be manufactured by sequentially laminating the insulating layers on upper and lower surfaces of the substrate.

In the conventional electronic component embedded printed circuit board like this, since soldering and reflow processes are repeated in every manufacturing process, a high temperature heat is applied to the laminate, and warpage of the substrate may occur whenever heating the laminate at high temperature. At this time, as the electronic component embedded in the substrate is made of a material having a different coefficient of thermal expansion (CTE) from the insulating layer bonded to the outside thereof, stress is concentrated on the bonding interface with the insulating layer due to repetition of the warpage of the substrate in every heating process, and as the process proceeds, delamination or lifting of the bonding interface occurs due to thermal shock.

### RELATED ART DOCUMENT

### Patent Document

Patent Document 1: Korean Patent Laid-open Publication No. 2012-0071938

### SUMMARY OF THE INVENTION

The present invention has been invented in order to overcome the above-described disadvantages and problems raised in the conventional printed circuit boards and it is, therefore, an object of the present invention to provide an electronic component embedded printed circuit board that can improve mechanical characteristics and reliability by preventing delamination between an electronic component embedded in a core and an insulating layer covering an outer peripheral surface of the electronic component.

In accordance with one aspect of the present invention to achieve the object, there is provided an electronic component embedded printed circuit board including: a core having a cavity therein and internal circuit layers on upper and lower surfaces thereof; an electronic component inserted in the cavity and having an elastic body on an outer peripheral surface thereof; insulating layers laminated on the top and bottom of the core; external circuit layers patterned on the insulating layers; and vias formed in the insulating layers to electrically connect the internal circuit layers and the external circuit layers, wherein among the vias, the via in contact with the electronic component may be connected through the elastic body.

The electronic component may be an MLCC including external electrodes provided on both sides and a main body provided between the external electrodes.

The elastic body may be provided on both or one surface of the electronic component except side surfaces and formed on the external electrode of the electronic component.

One end of the via passing through the elastic body may be in contact with the external electrode of the electronic component.

The elastic body may be one of elastomers and PDMS. In addition, the elastic body may be one of rubber, low-density polyethylene4, HDPE, polypropylene, bacteriophage capsid5, PET, polystyrene, nylon, diatom frustules, and medium-density fiberboard (MDF)7.

In accordance with another aspect of the present invention to achieve the object, there is provided a method for manufacturing an electronic component embedded printed circuit board, which includes the steps of forming a cavity in a core having internal circuit layers on upper and lower surfaces thereof; attaching a carrier having an adhesive member laminated on a base film to the lower surface of the core; inserting an electronic component in the cavity and fixing the electronic component onto the carrier by applying predetermined temperature and pressure to the top of the electronic component; forming an upper insulating layer on the top of the core having the electronic component embedded therein; removing the carrier so that a portion of the adhesive member remains on an outer peripheral surface of the electronic component in the form of a residue while removing the carrier attached to the lower surface of the core; forming a lower insulating layer on an opposite surface of the core having the upper insulating layer thereon; and forming external circuit layers on the upper and lower insulating layers to be electrically connected to the electronic component through vias.

In the step of removing the carrier, the unremoved adhesive member on the outer peripheral surface of the electronic component may function as an elastic body and be one of elastomers and PDMS having a lower modulus than the core and the electronic component.

Further, in the step of inserting the electronic component in the cavity, the electronic component may be pressed so that a lower surface of the electronic component is partially embedded in the adhesive member of the carrier by a pressure above 30 kgf/cm² in a temperature condition above 110° C.

And in the step of removing the carrier, the elastic body may be formed on an external electrode of the electronic component, where stress is concentrated, while being formed on the lower surface of the electronic component.

Among the vias formed in the upper and lower insulating layers, the via connected to the electronic component may be in contact with the external electrode and electrically connected through the elastic body formed on the external electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of an electronic component embedded printed circuit board in accordance with an embodiment of the present invention;

FIG. 2 is a plan view of a cavity forming region of the electronic component embedded printed circuit board in accordance with the present invention;

FIG. 3 is a SEM photograph of an electronic component applied to the electronic component embedded printed circuit board in accordance with the present invention;

FIGS. 4A-4F are process diagrams of a process of manufacturing an electronic component embedded printed circuit board in accordance with the present embodiment, wherein

FIG. 4A is a cross-sectional view showing the state in which a cavity is formed in a core;

FIG. 4B is a cross-sectional view showing the state in which an electronic component is inserted in the cavity of the core;

FIG. 4C is a cross-sectional view showing the state in which an upper insulating layer is formed on the core;

FIG. 4D is a cross-sectional view showing the state in which the carrier is removed from the core;

FIG. 4E is a cross-sectional view showing the state in which a lower insulating layer is laminated; and

FIG. 4F is a cross-sectional view showing the state in which external circuit layers are formed on the upper and lower insulating layers;

FIG. 5 is a schematic diagram of a bending evaluation test of the electronic component embedded printed circuit board in accordance with the present invention; and

FIGS. 6A and 6B are comparison photographs of a normal product of which an electronic component and an insulating layer are not delaminated and a defective product of which an electronic component and an insulating layer are delaminated.

### DETAILED DESCRIPTION OF THE PREFERABLE EMBODIMENTS

A matter regarding to an operational effect including a technical configuration for an object of an electronic component embedded printed circuit board and a method of manufacturing the same in accordance with the present invention will be clearly appreciated through the following detailed description with reference to the accompanying drawings showing preferable embodiments of the present invention.

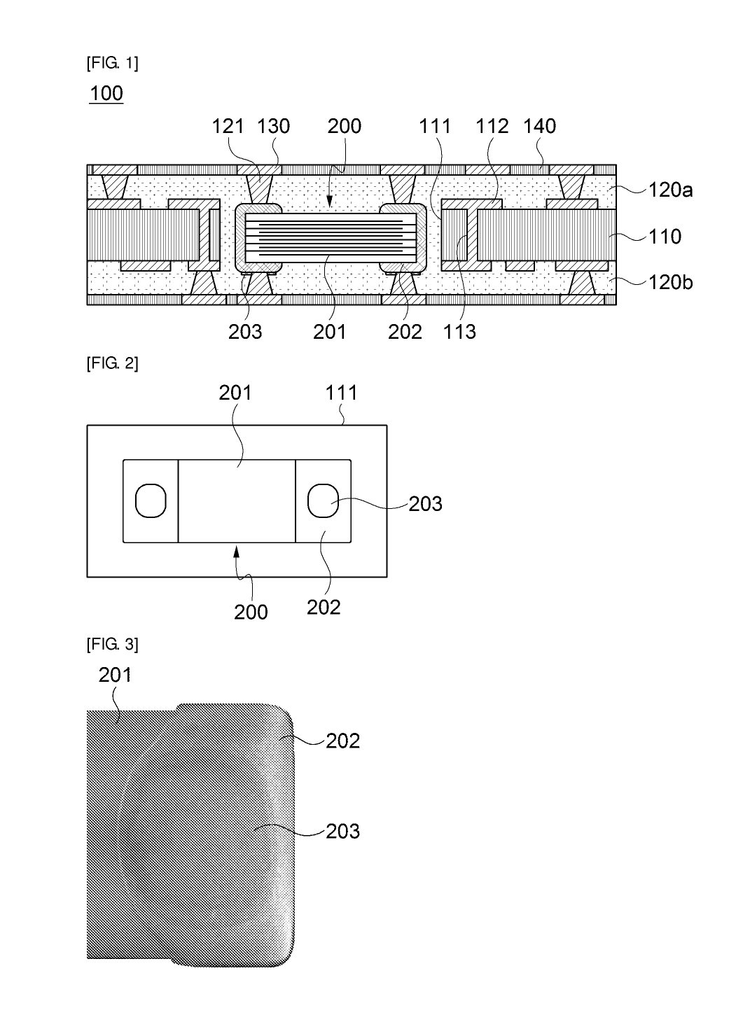

First, FIG. 1 is a cross-sectional view of an electronic component embedded printed circuit board in accordance with an embodiment of the present invention, FIG. 2 is a plan view of a cavity forming region of the electronic component embedded printed circuit board in accordance with the present invention, and FIG. 3 is a SEM photograph of an electronic component applied to the electronic component embedded printed circuit board in accordance with the present invention.

As shown, an electronic component embedded printed circuit board 100 of the present embodiment may consist of a core 110 having a cavity 111 formed therein, an electronic component 200 inserted in the cavity 111, insulating layers 120a and 120b laminated on the top and bottom of the core 110, and external circuit layers 130 provided on the insulating layers 120a and 120b.

At this time, a pair of external electrodes 202, which consist of a cathode and an anode, may be formed on an outer peripheral surface of the electronic component 200, and an elastic body 203 may be further formed on an outer peripheral surface of the external electrode 202.

In the electronic component embedded printed circuit board 100, although it is shown that the electronic component 200 embedded in the core 110 is embedded in one place, it is because only a unit is shown and thus it is not limited to one electronic component. The electronic component 200 may be embedded in a printed circuit board of each unit at regular intervals, and one or more electronic components 200 may be embedded according to the type of the embedded electronic component.

The cavity 111 may be formed in the core 110, which is positioned in the center of the electronic component embedded printed circuit board 100, in the shape of a through hole by laser processing or drilling using CNC. And the cavity 111 is preferred to have a width equal to or greater than that of the electronic component 200.

Further, circuit patterns may be patterned on upper and lower surfaces of the core 110 to form internal circuit layers 112, respectively, and the internal circuit layers 112 on the upper and lower surfaces may be electrically connected through a via or a through hole 113.

The electronic component 200 inserted in the cavity 111 of the core 110 may be active devices such as IC, semiconductor chip, and CPU in addition to passive devices such as MLCC and LTCC. At this time, a height of the electronic component is preferred to be equal to a height of the core 110 but may be higher than the height of the core 110.

At this time, when describing the electronic component 200 by taking the case of an MLCC shown in the drawing, an internal electrode may be formed in a main body 201, the cathode and anode external electrodes 202 may be formed on both sides of the main body 201, and the external electrodes 202 on the both sides may be physically and electrically connected to the external circuit layers 130 through vias 121, respectively.

Like this, since the printed circuit board 100 having the electronic component 200 embedded in the cavity 111 of the core 110 is manufactured by repeating reflow and soldering processes, concave or convex warpage may occur repeatedly due to the vertical asymmetry and difference in the coefficient of thermal expansion of the laminated materials.

In this printed circuit board 100, local stress concentration may occur in the formation region of the cavity 111, where the electronic component 200 and an insulating material, that is, different materials are inserted, due to the difference in the coefficient of thermal expansion between the core 110 and the electronic component 200 by the warpage generated during manufacturing processes. At this time, in case of the MLCC applied to the present embodiment, maximum stress is concentrated on the formation region of the external electrodes 202 on the both sides, which are made of a metal material having a relatively high modulus, and defects such as damage to the electronic component 200 or lifting of the insulating material may occur due to the concentration of the stress.

Accordingly, the elastic body 203 is preferred to be applied on the outside of the electronic component 200 embedded in the core 110 to mitigate the concentration of the stress transmitted to the electronic component 200 and prevent the lifting of the insulating material covering the electronic component 200.

The elastic body 203 may be formed to cover the entire outer peripheral surface of the electronic component 200. Further, since it is advantageous in terms of processes and cost savings that the elastic body 203 is limitedly applied on the region where the stress is concentrated, the elastic body 203 may be applied on one or both surfaces of the external electrode 202 made of a high modulus material. At this time, when the elastic body 203 is locally applied on one surface of the external electrode 202, the overall coefficient of thermal expansion in the insertion position of the electronic component 200 may not be reduced.

Since the material forming the core 110 of the printed circuit board 100 has a modulus of about 25 to 29 GPa and the copper (Cu) material forming the external electrode 202 of the electronic component 200 embedded in the core 110 has a modulus of about 117 GPa, the elastic body 203 is preferred to be made of a material having a lower modulus than the above materials.

Typically, it may be preferred that the elastic body 203 is made of polydimethylsilozane (PDMS). The reason of using PDMS as the elastic body 203 is because PDMS has a modulus of 360 KPa to 1.8 MPa, which is remarkably lower than the modulus of the core 110 and the external electrode 202 of the electronic component 200, and thus can have a relatively lower modulus of elasticity than the core 110 and the electronic component 200 to prevent the concentration of the stress on the region having a high modulus and PDMS is a material that can have a maximum elongation of 160% and thus can be configured in the form of a thin film to be used in the range that does not disturb the entire thickness of the printed circuit board 100.

Further, the elastic body 203 may be made of materials in the following Table 1 in addition to PDMS.

TABLE 1

| Elastic body | Modulus (GPa) |
|---|---|
| PDMS | 360 KPa~1.8 MPa |
| Rubber | 0.01~0.13 |
| Low-density polyethylene | 0.11~0.45 |
| HDPE | 0.8 |
| Polypropylene | 1.5~23 |
| Bacteriophage capsids | 1~3 |
| PET | 2~2.73 |
| Polystyrene | 3~3.53 |
| Nylon | 2~4 |
| Diatom frustules | 0.35~2.77 |
| Medium-density | 4 |
| fiberboard (MDF) | |

The elastic body 203 may be applied to be formed in a portion of the external electrode 202 of the electronic component 200 as shown in FIGS. 2 and 3, and may be applied to cover the entire external electrode 202 on one surface when necessary.

Further, in forming the elastic body 203 with a low modulus material, since the elastic body 203 may be formed by curing a liquid material, elasticity may be given by applying liquid PDMS with a uniform thickness using a liquid resin dispenser.

In addition, the elastic body may be provided by various methods such as printing, squeezing, and taping. This will be described in more detail in the following method for manufacturing a printed circuit board.

Like this, the insulating layers 120a and 120b may be formed on the top and bottom of the core 110 having the electronic component 200 embedded therein, respectively. The insulating layers 120a and 120b may be formed by laminating an insulating resin material such as prepreg and curing the insulating resin material. The insulating layers 120a and 120b may be closely coupled to the outer peripheral surface of the electronic component 200 during the lamination and curing of the insulating layers 120a and 120b.

And a plurality of vias 121 may be formed in the insulating layers 120a and 120b. As for the via 121, a via hole may be formed by laser processing or drilling using CNC like the cavity 111, and after processing the via hole, a plating layer may be formed on the upper surface of the insulating layers 120a and 120b including the inside of the via hole to form the via 121 in which the plating layer is filled. The external circuit layer 130 may be formed to be electrically connected to the electronic component 200 through the via 121 by patterning the plating layer on the insulating layers 120a and 120b.

A solder resist layer 140 may be further formed on the insulating layers 120a and 120b having the external circuit layer 130 thereon to protect the portions other than the circuit patterns exposed to the outside.

Meanwhile, among the vias 121 formed in the insulating layers 120a and 120b, the via 121 directly connected to the electronic component 200 may have one end connected to the external electrodes 202 on the both sides of the electronic component 200 and the other end connected to the circuit pattern forming the external circuit layer 130 to thereby form electrical connection between the electronic component 200 and the external circuit layer 130. At this time, in connecting the electronic component 200 to the external circuit layer 130 through the via 121, the via 121 may be connected to both of the upper and lower surfaces of the external electrode 202 or the via 121 may be connected to only one of the upper and lower surfaces of the external electrode 202.

Here, as described above, one end of the via 121, which is connected to the external electrode 202 by forming the elastic body 203 on the entire outer peripheral surface of the electronic component 200 or on the external electrode 202 of the electronic component 200, is preferred to be formed through the elastic body 203.

The electronic component embedded printed circuit board 100 configured like this can prevent damage to the electronic component 200 or lifting of the insulating layer by applying the PDMS elastic body 203 on the entire surface or a portion of the outer peripheral surface of the electronic component 200 embedded in the core 110 to disperse the stress concentrated on the electronic component 200 by the elasticity formed on the interface between the insulating layers 120a and 120b and the electronic component 200.

Method for Manufacturing Electronic Component Embedded Printed Circuit Board

A method for manufacturing a printed circuit board in accordance with an embodiment of the present invention will be described below with reference to the following drawings.

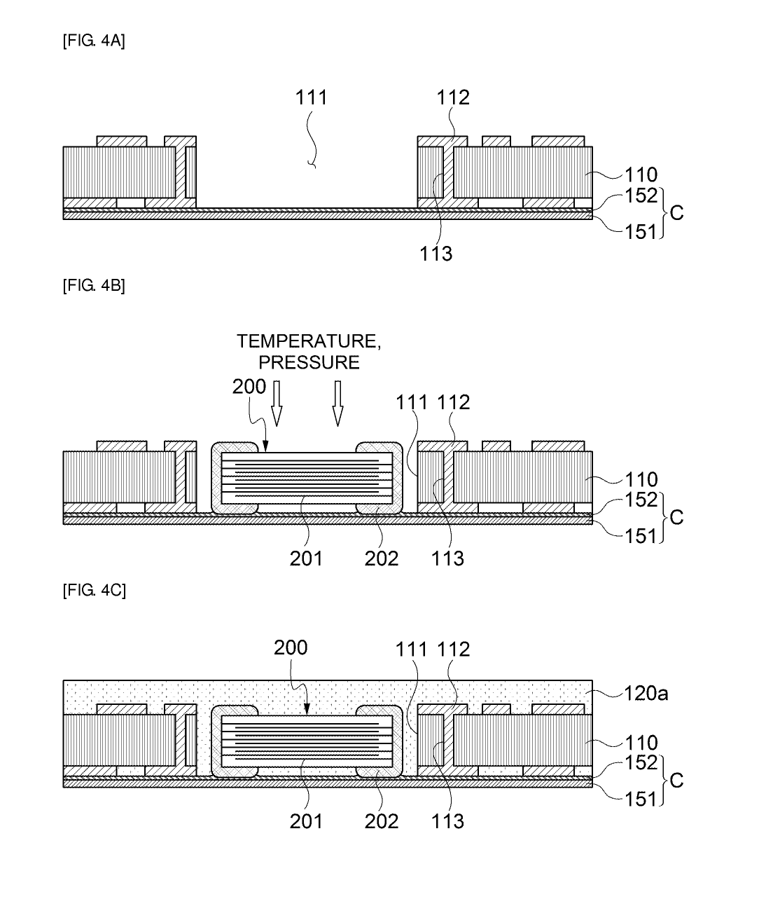

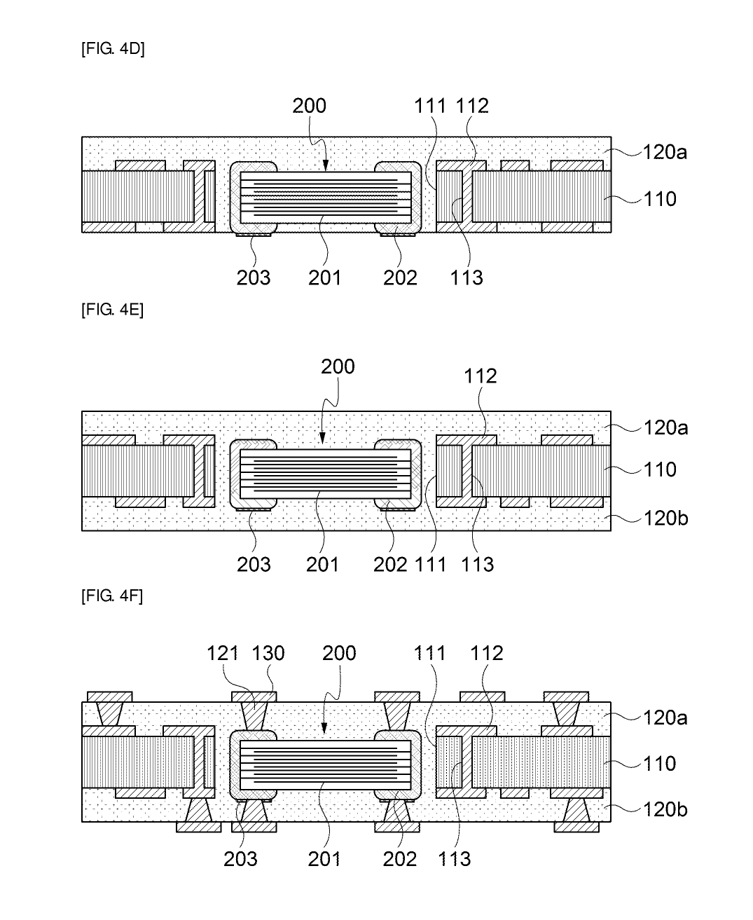

First, FIGS. 4A-4F are process diagrams showing a process of manufacturing an electronic component embedded printed circuit board in accordance with the present embodiment.

First, FIG. 4A is a cross-sectional view showing the state in which a cavity is formed in a core. As shown, the cavity 111 may be formed in the core 110, which is made of an insulating material, in the shape of a through hole. The cavity 111 may be formed by laser processing or drilling. The cavity 111 is formed with a predetermined size and may be formed with a width equal to or greater than a width of an electronic component 200 inserted therein.

At this time, in addition to the forming conditions of the cavity 111, a via 113 may be formed in the core 110 to electrically connect internal circuit layers 112, and the cavity 111 may be formed at the same time when the via 113 is formed.

After that, a carrier C may be attached to a lower surface of the core 110. The carrier C, which is a member for fixing a position of the electronic component 200 when inserting the electronic component 200 in the cavity 111 formed as a through hole, prevents the electronic component 200 from being separated from the cavity 111 and fixes the electronic component 200 by an elastic adhesive member applied on an upper surface thereof.

At this time, as for the carrier C, the elastic adhesive member 152 may be applied on a base film 151 shown in FIG. 4A. The base film 151 may be mainly made of resin materials such as PI and PET. The adhesive member 152 applied on the base film 151 may be made of materials such as elastomers and PDMS. In addition, one of the materials having a predetermined elasticity listed in Table 1 may be selected.

Next, FIG. 4B is a cross-sectional view showing the state in which the electronic component is inserted in the cavity of the core. As shown, the electronic component 200 may be inserted in the cavity 111 of the core 110 to be positioned on the carrier C. Preferably, the electronic component 200 is an electronic component having the same height as the thickness of the core 110.

After the step of inserting the electronic component 200 in the cavity 111, the electronic component 200 may be fixed onto the carrier C by applying predetermined temperature and pressure. When the electronic component 200 is fixed onto the carrier C, all or a portion of a lower surface of the electronic component 200 may be in contact with the adhesive member 152 of the carrier C. Preferably, all or a portion of the lower surface of the electronic component 200 may be embedded in the adhesive member 152.

The reason why a portion of the electronic component 200 is embedded in the adhesive member 152 by applying the predetermined pressure and temperature to the electronic component 200 is to leave a residue of the adhesive member 152 on one surface of the electronic component 200 in the step of removing the carrier C, which will be described later. This will be described below in more detail.

Next, FIG. 4C is a cross-sectional view showing the state in which an upper insulating layer is formed on the core. As shown, the upper insulating layer 120a may be formed on the core 110 having the electronic component 200 embedded therein. The upper insulating layer 120a may be formed by laminating an insulating material and cured with a predetermined thickness by heating and pressing the insulating material. At this time, the insulating material may be partially introduced into a space between the cavity 111 of the core 110 and the electronic component 200 when heated and pressed and cured to fix the electronic component 200. Apart from this, before forming the upper insulating layer 120a, a separate adhesive may be injected between the electronic component 200 and a sidewall of the cavity 111 to fix the electronic component 200.

After that, FIG. 4D is a cross-sectional view showing the state in which the carrier is removed from the core. As shown, when the lamination of the upper insulating layer 120a on the core 110 having the electronic component 200 embedded therein is completed, the carrier C attached to the lower surface of the core 110 may be removed. Since a plurality of layers of the base film 151 and the adhesive member 152 of the carrier C are removed from the lower surface of the core 110 at the same time, the carrier C may be removed so that a portion of the adhesive member 152 is not removed to be left on the surface bonded to the electronic component 200 in the form of a residue, and the residue type adhesive member 152 may function as an elastic body 203 and may be preferred to be mainly made of a resin material such as elastomers or PDMS having a lower modulus than the core 110 or the electronic component 200.

The elastic body 203 may be formed all over one surface of the electronic component 200 in contact with the adhesive member 152, but in case of an MLCC, the elastic body 203 may be partially formed only on an external electrode 202 which is mainly in contact with the adhesive member 152 since the external electrode 202 projects outside a main body 201. At this time, in order to form the residue of the adhesive member 152 as the elastic body 203 when the carrier C is removed, it is preferred to maintain specific pressure and temperature or higher during heating and pressing in the step of inserting the electronic component 200 in the cavity 111. That is, if it is maintained below the specific pressure and temperature during the fixation of the electronic component 200, the elastic body 203 cannot be provided since all the adhesive member 152 is removed during the removal of the carrier C.

In the insertion of the electronic component 200 like this, pressing conditions can be understood through the following Table 2. Temperature and pressure conditions are evaluated through 2 factors 4 levels DOE. As listed in Table 2, as the result of the evaluation, it can be understood that the residue of the adhesive member 152, which functions as the elastic body 203, can remain in a pressing condition above 30 kgf/cm² at a temperature above 110° C.

TABLE 2

| | | | Elastic body |
|---|---|---|---|
| | Temperature | Pressure | residue |
| 1 | 100 | 40 | X |
| 2 | 120 | 20 | X |
| 3 | 110 | 30 | ◯ |
| 4 | 90 | 30 | X |
| 5 | 90 | 10 | X |
| 6 | 110 | 40 | ◯ |
| 7 | 100 | 20 | X |
| 8 | 120 | 40 | ◯ |
| 9 | 90 | 20 | X |
| 10 | 120 | 10 | X |
| 11 | 110 | 20 | X |
| 12 | 110 | 10 | X |
| 13 | 100 | 10 | X |
| 14 | 90 | 40 | X |
| 15 | 120 | 30 | ◯ |
| 16 | 100 | 30 | X |

Next, FIG. 4E is a cross-sectional view showing the state in which a lower insulating layer is laminated. As shown, the lower insulating layer 120b may be laminated on an opposite surface of the upper insulating layer 120a in the same manner as the upper insulating layer 120a by reversing the core 110 having the upper insulating layer 120a thereon. The formation of the insulating layers 120a and 120b may be completed as in FIG. 4E by curing the lower insulating layer 120b through heating and pressing.

Finally, FIG. 4F is a cross-sectional view showing the state in which external circuit layers are formed on the upper and lower insulating layers. As shown, a plurality of via holes 121 may be formed in the upper and lower insulating layers 120a and 120b, a plating layer may be formed inside the via hole 121 and on the upper and lower insulating layers 120a and 120b, and the external circuit layer 130 may be formed by patterning the plating layer through etching to complete the manufacture of the electronic component embedded printed circuit board.

At this time, in the step of forming the via holes in the upper and lower insulating layers 120a and 120b, the via 121 in contact with the external electrode 202 of the electronic component 200 having the elastic body 203 is preferred to be electrically connected through the elastic body 203.

And the elastic body 203 may be formed on the external electrode 202 of the electronic component 200 but may be formed only on one surface of the external electrode 202 or formed on both surfaces of the external electrode 202.

Evaluation of Bonding Reliability of Electronic Component of Electronic Component Embedded Printed Circuit Board

Bonding reliability of the electronic component of the electronic component embedded printed circuit board manufactured as in FIG. 1 through the above manufacturing process is tested by the standard specifications. Looking into the results of the test, it can be understood that the bonding reliability is improved when manufacturing the printed circuit board by forming the elastic body on the outer peripheral surface of the electronic component than when manufacturing the printed circuit board without forming the elastic body on the outer peripheral surface of the electronic component as below.

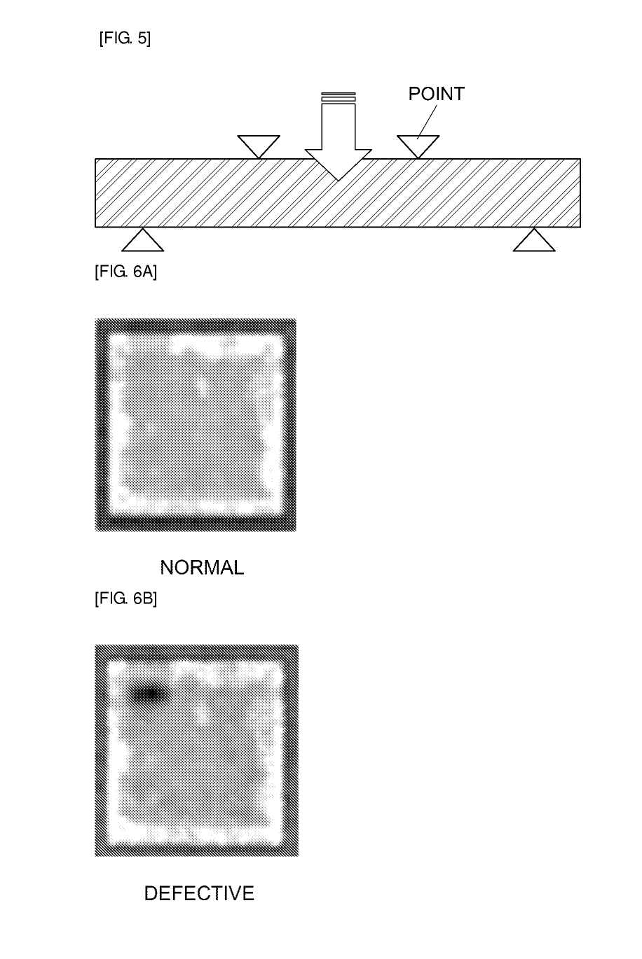

In the electronic component embedded printed circuit board manufactured through the manufacturing method of the present invention, the evaluation of the bonding reliability of the electronic component embedded in the printed circuit board and the insulating layer is performed by a bending test according to the standard specifications of JESDEC-9702 as shown in FIG. 5 when the manufacture of the printed circuit board is completed. The bending test of the printed circuit board is performed by applying pressure to four points through a commercial bending evaluation tester, pressing to a depth of 100 μm to generate warpage, and repeating bending 20000 times twice per second at a frequency of 2 Hz, and the results are evaluated.

As the result of the evaluation by the above specifications, delamination of the electronic component 200 and the insulating layer 120 is checked through an ultrasonic microscope by comparing the printed circuit board in which the electronic component 200 having the elastic body 203 is embedded with the printed circuit board in which the electronic component 200 without the elastic body 203 is embedded. FIGS. 6A-6B show comparison photographs of a normal product in which the electronic component and the insulating layer are not delaminated and a defective product in which the electronic component and the insulating layer are delaminated as the result of the bending test of the electronic component embedded printed circuit board. When the electronic component is delaminated from the insulating layer, a delamination position of the electronic component is identified as black like the photograph on the right. Thus, actual occurrence of the delamination between the electronic component and the insulating layer is checked through a cross-sectional analysis of the printed circuit board.

Further, as shown in Table 3, when looking into the results of the bending test of the printed circuit board in which the elastic body is formed on the external electrode of the electronic component and the printed circuit board in which the elastic body is not formed on the external electrode of the electronic component, it is checked that the bonding reliability is greatly improved in two cases in which an adhesive coating layer is formed on the electronic component than the case in which the adhesive coating layer is not formed on the electronic component.

At this time, as shown in Table 3, it can be understood that the bonding reliability is greatly improved depending on whether the elastic body 203 is applied on the external electrode 202 or not, and it is checked that the improvement of the bonding reliability depending on the application of the elastic body on one or both surfaces of the external electrode 202 is slight. Therefore, the electronic component embedded printed circuit board according to the present invention is preferred to improve the bonding reliability by providing the elastic body on one surface of the external electrode of the electronic component.

TABLE 3

| | | Number of |
|---|---|---|
| | | delamination |
| | Bending test | defects |
| Not applied | 20000 times | 17/200 |
| Applied on only one | 20000 times | 1/200 |
| surface of electrode | | |
| Applied on both | 20000 times | 2/200 |
| surfaces of electrode | | |

As described above, the printed circuit board and the method for manufacturing the same according to the present invention can improve the bonding reliability of the insulating layers laminated on the top and bottom of the core and the surface of the electronic component by forming the elastic body on the surface or the external electrode of the electronic component embedded in the core and prevent substrate defects and improve the yield of the printed circuit board products by improving coupling performance of the insulating layer and the electronic component to prevent delamination and lifting of the insulating layer from the electronic component.

Further, the present invention can prevent the damage to the electronic component or the lifting of the insulating layer by dispersing the stress concentrated on the electronic component through the elasticity formed on the interface between the insulating layer and the electronic component by the elastic body formed on the electronic component.

The above-described preferred embodiments of the present invention are disclosed for the purpose of exemplification and it will be appreciated by those skilled in the art that various substitutions, modifications and variations may be made in these embodiments without departing from the technical spirit of the present invention. Such substitutions and modifications are intended to be included in the appended claims.

What is claimed is:

1. An electronic component embedded printed circuit board comprising:
a core having a cavity therein and internal circuit layers on upper and lower surfaces thereof;
an electronic component inserted in the cavity and having an elastic body on an outer peripheral surface thereof;
insulating layers laminated on the top and bottom of the core;
external circuit layers patterned on the insulating layers; and
vias formed in the insulating layers to electrically connect the internal circuit layers and the external circuit layers, wherein among the vias, the via in contact with the electronic component is connected through the elastic body.

2. The electronic component embedded printed circuit board according to claim 1, wherein the electronic component is a multilayer ceramic capacitor (MLCC) comprising external electrodes provided on both sides and a main body provided between the external electrodes.

3. The electronic component embedded printed circuit board according to claim 2, wherein the elastic body is provided on both or one surface of the electronic component except side surfaces of the electronic component.

4. The electronic component embedded printed circuit board according to claim 2, wherein the elastic body is formed on the external electrode of the electronic component.

5. The electronic component embedded printed circuit board according to claim 1, wherein one end of the via passing through the elastic body is in contact with the external electrode of the electronic component.

6. The electronic component embedded printed circuit board according to claim 1, wherein the elastic body is one of elastomers and polydimethylsiloxane (PDMS).

7. The electronic component embedded printed circuit board according to claim 6, wherein the elastic body is one of rubber, low-density polyethylene, high-density polyethylene (HDPE), polypropylene, bacteriophage capsids, polyethylene terephthalate (PET), polystyrene, nylon, diatom frustules, and medium-density fiberboard (MDF) in addition to one of elastomers and polydimethylsiloxane (PDMS).

8. The electronic component embedded printed circuit board according to claim 1, wherein the insulating layer fills a space between the cavity and the electronic component.

9. A method for manufacturing an electronic component embedded printed circuit board, comprising:
forming a cavity in a core having internal circuit layers on upper and lower surfaces thereof;
attaching a carrier having an adhesive member laminated on a base film to the lower surface of the core;
inserting an electronic component in the cavity and fixing the electronic component onto the carrier by applying predetermined temperature and pressure to the top of the electronic component;
forming an upper insulating layer on the top of the core having the electronic component embedded therein;
removing the carrier so that a portion of the adhesive member remains on an outer peripheral surface of the electronic component in the form of a residue while removing the carrier attached to the lower surface of the core;
forming a lower insulating layer on an opposite surface of the core having the upper insulating layer thereon; and
forming external circuit layers on the upper and lower insulating layers to be electrically connected to the electronic component through vias.

10. The method for manufacturing an electronic component embedded printed circuit board according to claim 9, wherein in removing the carrier, the unremoved adhesive member on the outer peripheral surface of the electronic component functions as an elastic body.

11. The method for manufacturing an electronic component embedded printed circuit board according to claim 9, wherein the adhesive member is one of elastomers and polydimethylsiloxane (PDMS) having a lower modulus than the core and the electronic component.

12. The method for manufacturing an electronic component embedded printed circuit board according to claim 11, wherein the adhesive member is one of rubber, low-density polyethylene, high-density polyethylene (HDPE), polypropylene, bacteriophage capsids, polyethylene terephthalate (PET), polystyrene, nylon, diatom frustules, and medium-density fiberboard (MDF) in addition to one of elastomers and polydimethylsiloxane (PDMS).

13. The method for manufacturing an electronic component embedded printed circuit board according to claim 9, wherein in inserting the electronic component in the cavity, the electronic component is pressed so that a lower surface of the electronic component is partially embedded in the adhesive member of the carrier by a pressure above 30 kgf/cm² in a temperature condition above 110° C.

14. The method for manufacturing an electronic component embedded printed circuit board according to claim 10, wherein in removing the carrier, the elastic body is formed on an external electrode of the electronic component, where stress is concentrated, while being formed on the lower surface of the electronic component.

15. The method for manufacturing an electronic component embedded printed circuit board according to claim 10, wherein among the vias formed in the upper and lower insulating layers, the via connected to the electronic component is in contact with the external electrode and electrically connected through the elastic body formed on the external electrode.

16. The method for manufacturing an electronic component embedded printed circuit board according to claim 9, further comprising, after forming the external circuit layers, forming solder resist layers to protect portions except the external circuit layers exposed to the upper and lower insulating layers.
